(19) United States
(12) Patent Application Publication
(10) Pub. No.: US 2008/0153012 A1
(43) Pub. Date: Jun. 26, 2008

(54) Method of measuring the overlay accuracy of a multi-exposure process

(75) Inventors: George Liu, Ping-Cheng City (TW); Vencent Chang, Taipei City (TW); Chia-Chen Chen, Hsin-Chu City (TW)

Correspondence Address: NIXON & VANDERHYE, PC, 901 NORTH GLEBE ROAD, 11TH FLOOR, ARLINGTON, VA, 22203, US

(73) Assignee: UNITED MICROELECTRONICS CORP., Hsin-Chu City (TW)

(21) Appl. No.: 12/068,900

(22) Filed: Feb. 13, 2008

Related U.S. Application Data
(62) Division of application No. 10/834,117, filed on Apr. 29, 2004.

(51) Int. Cl. G03F 7/20

(52) U.S. Cl. 430/5

(57) ABSTRACT

A method of measuring the overlay accuracy of a multi-exposure process is provided. The characteristic of this invention is utilizing a scanning electron microscope for monitoring the overlay accuracy real-time during the multi-exposure processes in stead of the conventional optical measurement method.

### CROSS REFERENCE TO RELATED APPLICATION

This application is a divisional of U.S. patent application Ser. No. 10/834,117 filed Apr. 29, 2004.

### BACKGROUND OF THE INVENTION

1. Field of the Invention

This invention relates to a method of measuring the overlay accuracy, and more particularly to measure the overlay accuracy of the multi-exposure process.

2. Description of the Prior Art

### SUMMARY OF THE INVENTION

In the semiconductor fabrication process, the wafer is sawed along scribe lines into a plurality of chips. Overlay marks are arranged on the scribe lines at the four corners of the edge of each chip to measure whether the test pattern of the mask is precisely transferred to the photoresist layer and aligned with the previous layer of the wafer after a photolithography process. By the above test exposure process, the parameters of the formal exposure process will be adjusted on the basis of the overlay information from the overlay marks.

A conventional method for measuring the overlay accuracy is utilizing an Overlay apparatus to scan the overlay marks on the scribe lines of each chip for acquiring the overlay information. FIG. 1A shows a vertical view of a conventional structure of an overlay mark 100, and FIG. 1B illustrates a cross-sectional structure of the overlay mark 100 taken along a cutting line 1B-1B′ of FIG. 1A.

First, referring to FIG. 1A and FIG. 1B, four outer recesses 102 are formed on a previous layer 106 above a substrate layer 108. The outer recesses 102 of the overlay mark 100 are respectively formed into a first rectangle, and each outer recess 102 is a side of the first rectangle and the adjacent sides are not connected. The hollow structure of the outer recesses 102 can be the result from an etching process on the previous layer 106 or the result of filling to a trench (not shown) of the substrate layer 108 by the previous layer 106. The outer recess 102 is used as a reference mark for a following test exposure process to measure whether a photoresist pattern is precisely aligned with it from a mask.

Next, referring to FIG. 1A, four inner photoresist patterns 104 are transferred and formed from a test mark (not shown) to the previous layer 106 by a photolithography process (comprises photoresist coating, exposure and development processes). The inner patterns 104 of the overlay mark 100 are also respectively formed into a second rectangle and are enclosed by the first rectangle. Each inner photoresist pattern 104 is a side of the second rectangle and the adjacent sides are not connected. Four outer recesses 102 and four inner photoresist patterns 104 could be divided into a vertical mark and a horizontal mark. FIG. 1B just shows a cross-sectional structure of the vertical mark of the overlay mark 100 taken along the cutting line 1B-1B′ of FIG. 1A. A vertical centerline (not shown) of the opposite inner photoresist patterns 104 is set to match another vertical centerline (not shown) of the opposite outer recesses 102 when the mask is initially aligned with the previous layer 106. And the alignment of horizontal mark of the overlay mark 100 are also be set as the same way of the vertical mark as above.

After the inner photoresist patterns 104 were formed, an Overlay apparatus (not shown) is used to detect the overlay mark 100 with a optical scanning, along with the vertical direction for the horizontal mark and the horizontal direction for the vertical mark of the overlay mark 100. FIG. 1C shows the return signal waveform from the vertical mark of the overlay mark 100 as shown in FIG. 1B. The peak signals of the outer recesses 102 in FIG. 1B are read first and denoted as 102′ and 102′ in FIG. 1C, and the peak signals of the inner photoresist patterns 104 are then read and denoted as 104′ and 104′. Next, the mean value of the peak signals 102′ and 102′ is obtained and expressed it by a dotted midline 110, and the mean value of the peak signals 104′ and 104′ is also obtained and expressed it by another dotted midline 112 in FIG. 1C. The related position and shift distance of the midlines 110 and 112 will be calculated as a horizontal error from the overlay mark 100. And the vertical error of the overlay mark 100 will also be calculated as the same way by the scanning to the horizontal mark. Finally, an overlay error composed of the vertical error and the horizontal error of the overlay mark 100 is obtained.

Four overlay errors, collected from the overlay marks 100 on four corners of the chip will help to judge whether a scale error, a rotation error, or a translation error is occur during this test exposure process. And the parameters of the following formal exposure process will be adjusted when this test exposure process is not reaching the required accuracy.

The above conventional method for measuring the overlay error is utilizing an Overlay apparatus to scan the overlay marks 100 on the scribe lines of each chip for acquiring the overlay information. But the optical detecting resolution is depended on the wavelength of the light source in the Overlay apparatus. Hence, the scale of the overlay mark 100 must reach a recognizable size to cooperate with the specific Overlay apparatus.

The conventional method for monitoring the alignment accuracy of the photolithography process is utilizing an Overlay apparatus to scan the overlay marks 100 at a specific time. The conventional method cannot provide a real-time monitoring of alignment accuracy; hence, the time spent in this alignment step will increase and influence the whole semiconductor fabrication process.

The conventional method is used for the single exposure process to measure whether the photoresist patterns 104 transferred from a mask are precisely aligned with the recesses 102 in the scribe lines of the chip. Hence, in a multi-exposure process, the conventional method cannot be used to measure whether the latter photoresist patterns transferred from a second mask are precisely aligned with the former photoresist patterns transferred from a first mask.

### BRIEF DESCRIPTION OF THE DRAWINGS

FIG. 1A illustrates a vertical view of a conventional structure of an overlay mark.

FIG. 1B illustrates a cross-sectional structure of the overlay mark.

FIG. 1C illustrates a return signal waveform from a vertical mark of the overlay mark from the conventional detecting process.

FIG. 2A illustrates a vertical view of a first overlay check pattern on a first mask according to a first preferred embodiment of the present invention.

FIG. 2B illustrates a vertical view of a second overlay check pattern on a second mask.

FIG. 2C illustrates a vertical view of a first trench and a second trench on a photoresist layer.

FIG. 2D illustrates a cross-sectional structure of a first vertical trench and a second vertical trench on the photoresist layer.

FIG. 3A illustrates a vertical view of a first overlay check pattern on a first mask according to a second referred embodiment of the present invention.

FIG. 3B illustrates a vertical view of a second check pattern on a second mask.

FIG. 4A illustrates a vertical view of a first overlay check pattern on a first mask according to a third preferred embodiment of the present invention.

FIG. 4B illustrates a vertical view of a second overlay check pattern on a second mask.

FIG. 4C illustrates a vertical view of a first trench and two second trenches on a photoresist layer.

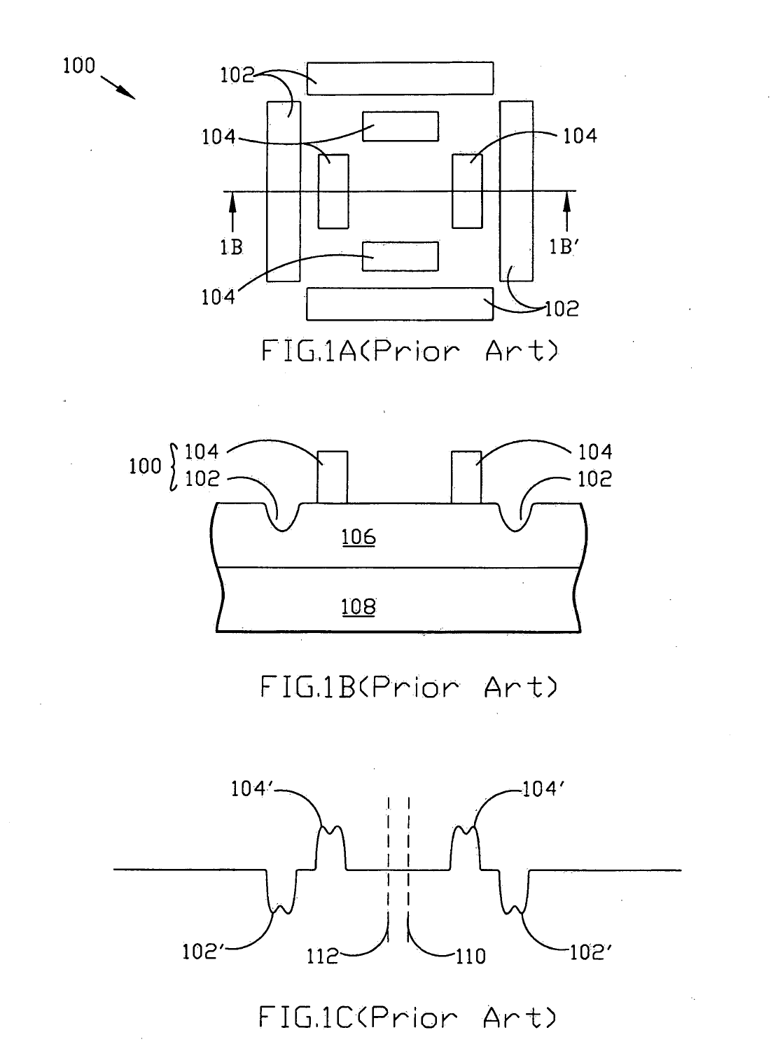

### DESCRIPTION OF THE PREFERRED EMBODIMENT

The present invention has been made in view of the above problems of the conventional method for measuring the overlay accuracy by utilizing an Overlay apparatus. The present invention is providing a method for measuring the overlay tolerance during a multi-exposure process. According to the present invention, a scanning electron microscope (SEM), providing a high detecting resolution is utilized for monitoring the overlay accuracy instead of the overlay apparatus of the conventional method.

The scanning electron microscope could be used to observe the surface structure of a specimen. A high-energy electron beam, emitted from an electron gun of the scanning electron microscope, was incident to the entire surface of the specimen, causing secondary signals (i.e. secondary electrons) to be ejected from the surface of the specimen and then collected and counted by an electronic detector. Finally, an image of the surface structure of the specimen could be obtained and monitored. Because electrons have a much smaller wavelength than light, they can resolve smaller structures than light can. Hence, in the following statement of a preferred embodiment of the present invention, a SEM is used to monitor the overlay accuracy by scanning the trenches transferred by different masks during a multi-exposure process.

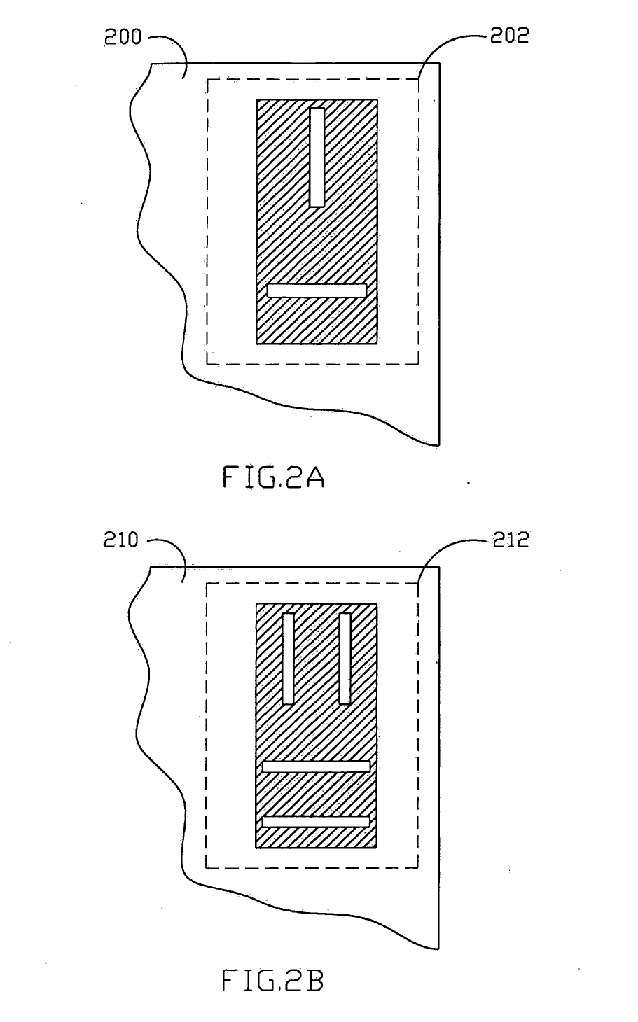

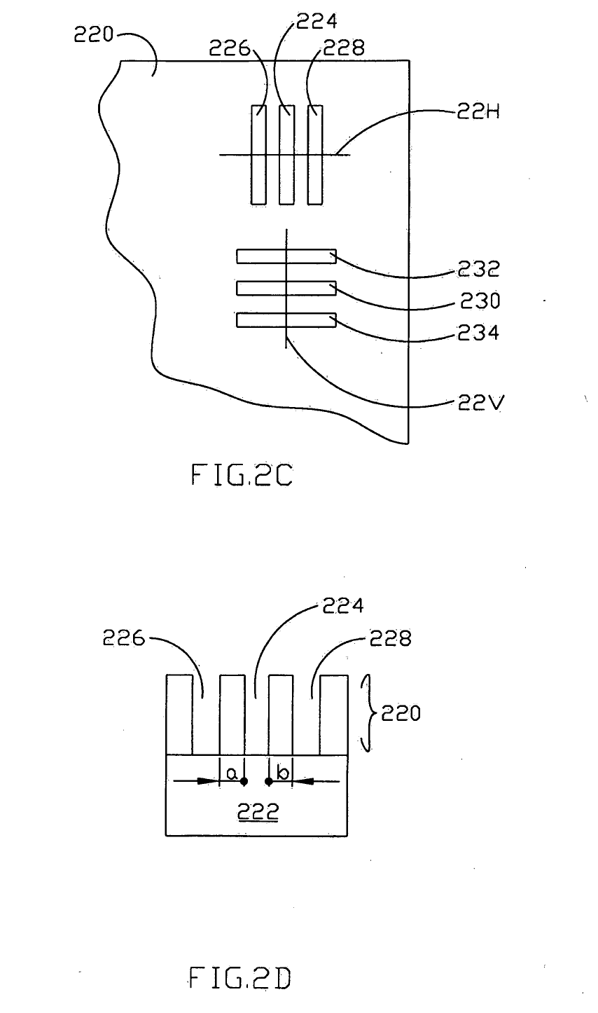

A first preferred embodiment of the present invention is providing a method to measure the overlay accuracy of a multi-exposure process. First, four of the first overlay check patterns 202 are formed at four corners of a first mask 200, and a vertical view of a first overlay check pattern 202 is shown in FIG. 2A. Referring to FIG. 2A, a first vertical-trench pattern and a first horizontal-trench pattern are provided on each first overlay check pattern 202. Then, a first photolithography process is executed (comprises photoresist coating, exposure and development processes), transferring four first overlay check patterns 202 to a photoresist layer 220 with the positive photoresist process, and four first trenches are formed on a photoresist layer 220. Each first trench is composed of a first vertical trench 224 and a first horizontal trench 230 shown in FIG. 2C. In this first preferred embodiment of the present invention, the first mask 200 is provided with four first overlay check patterns 202. But the number of the first overlay check pattern 202 is not restricted to four according the present invention, and the position and the arrangement of the first overlay check pattern 202 is not limited to the four corners of a first mask 200.

Next, four second overlay check patterns 212 are formed at four corners of a second mask 210 (corresponding to the four corners of the first mask), and a vertical view of a second overlay check pattern 212 is shown in FIG. 2B. Referring to FIG. 2B, two second vertical-trench patterns and two second horizontal-trench patterns are provided on each second overlay check pattern 212, and between the two second vertical-trench patterns, the corresponding first vertical-trench pattern is aligned as the midline, and between the two second horizontal-trench patterns, the corresponding first horizontal-trench pattern is aligned as the midline. Afterward, a second photolithography process is executed (comprises exposure and development process), transferring four second overlay check patterns 212 to the photoresist layer 220 with the positive photoresist process, and four second trenches are formed on the photoresist layer 220. Each second trench is composed of two second vertical trenches 226, 228 and two second horizontal trenches 232, 234 shown in FIG. 2C.

A vertical view of a first trench formed on the photoresist layer 220 by the first photolithography process and a second trench formed on the photoresist later 220 by the second photolithography process are shown in FIG. 2C. The arrangement of the first vertical trench 224 and the two second vertical trenches 226, 228 could be passed through by a horizontal scan line 22H, and the horizontal scan line 22H is perpendicular to the first vertical trench 224. The arrangement of first horizontal trench 230 and the two second horizontal trenches 232, 234 could also be passed through by a vertical scan line 22V, and the vertical scan line 22V is perpendicular to the first horizontal trench 230. Hence, taking the horizontal scan line 22H as the section-line for the photoresist layer 220, the relative positions between the first vertical trench 224 and the two second vertical trenches 226, 228 could be observed in FIG. 2D. Referring to FIG. 2D, first, the photoresist layer 220 is formed above a previous layer 222 by the first photolithography process. Then the first vertical trench 224 is formed on the photoresist layer 222. Finally, the two second trenches 226, 228 are formed on two sides of the first vertical trench 224 and have individual intervals a and b to the first vertical trench 224.

In this first preferred embodiment according to the present invention, in order to measure the overlay accuracy for the second mask 210 to the first mask 200, the positions of the second overlay check patterns 212 arranged on the second mask 210 must correspond with the positions of the first overlay check patterns 202 arranged on the first mask 200. After the first trench transferred from the first overlay check pattern 202 of the first mask 200 is formed on the photoresist layer 220, the second trench transferred from the second overlay check pattern 212 will be formed on the same photoresist layer 220 on the principle of making the intervals from the first vertical trench 224 to the adjacent second vertical trenches 226 and 228 to be equal. And the intervals from the first horizontal trench 230 to the adjacent second horizontal trenches 232 and 234 are also arranged to be equal when the second mask 210 has no overlay error with the first mask 200. According to the above arrangement, the overlay accuracy between the second mask 210 and the first mask 200 in a multi-exposure process could be detected by measuring whether the intervals between the first trench and the second trenches are equal or not.

Afterward, a scanning electron microscope (not shown) is used to detect the intervals from the first trench to the adjacent second trenches to obtain an overlay error between the second mask 210 and the first mask 200. The intervals from the first vertical trench 224 to the adjacent second vertical trenches 226 and 228 are measured, scanned along the horizontal scan line 22H to get a horizontal overlay error of the overlay error. And the intervals from the first horizontal trench 230 to the adjacent second horizontal trenches 232 and 234 are measured and are scanned along the horizontal scan line 22V to get a vertical overlay error by the scanning electron microscope. Referring to FIG. 2D and taking the first vertical trench 224 and the second vertical trenches 226, 228 as an example, the shift-direction of the horizontal overlay error depends on the magnitude of the intervals a and b. If the interval a is greater than the interval b, it means that the second vertical trenches 226, 228 transferred from the second mask 210 has a shift-movement toward the leaf from the first vertical trench 224 transferred from the first mask 200. And if the interval a is smaller than the interval b, the direction of the horizontal overlay error could be observed toward the right. Then the magnitude of the horizontal overlay error could be calculated as half the difference between the intervals a and b. The vertical overlay error, determined by the intervals between the first horizontal trench 230 and the adjacent second trenches 232, 234 is also measured by the same way as the horizontal overlay error in the above description.

In this first preferred embodiment according to the present invention, an overlay error composed of a horizontal overlay error and a vertical overlay error could be calculated by scanning the positions of the first trench and the second trench formed at one corner of the photoresist layer 220. And the whole overlay result between the first mask 200 and the second mask 210 could be obtained by collecting four overlay errors arranged at four corners of the photoresist layer 220.

In this first preferred embodiment of the present invention, the amount and the positions of the first trench and the second trench are dependent on the first overlay check pattern 202 of the first mask 200 and the second overlay check pattern 212 of the second mask 210. But the positions of first trench and the second trench are not limited to arrange on the scribe lines of each chip, other positions in the principle of not influence the original layout during the multi-exposure process also could be arranged to form the first trench and the second trench. In addition, the first mask 200 and the second mask 210 are not limited to be used on the adjacent exposure process during a multi-exposure process, the overlay accuracy between any two masks could be calculated by arranging a first overlay check pattern and a second overlay check pattern, as described in the above description of the first preferred embodiment according to the present invention.

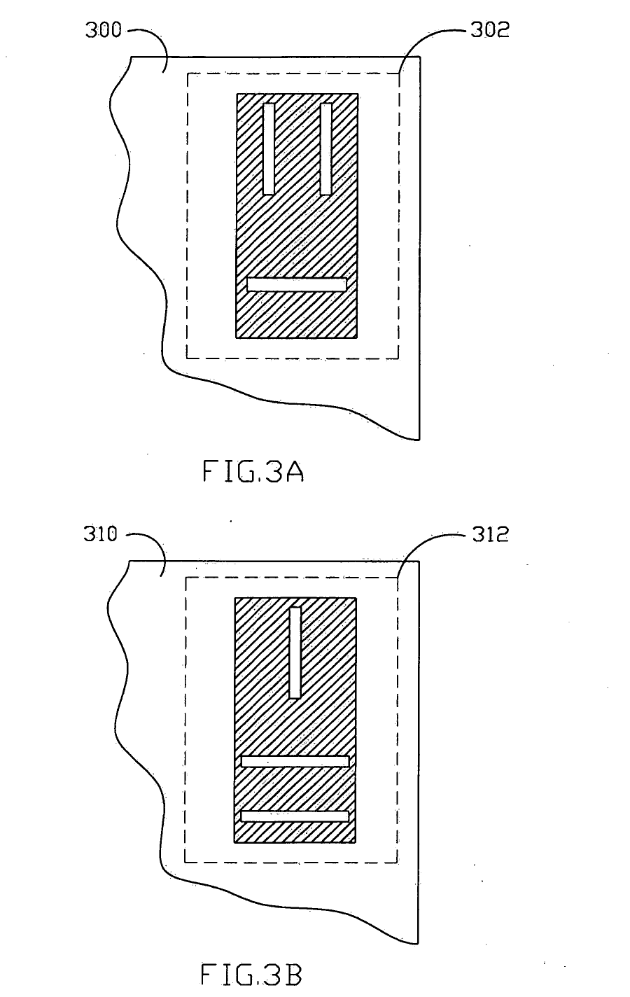

In this first preferred embodiment of the present invention, the forming position of the second vertical-trench patterns are parallel but not overlap with the forming position of the first vertical-trench pattern, and the forming position of the second horizontal-trench patterns are parallel but not overlap with the forming position of the first horizontal-trench pattern. But according to the present invention, the forms of the first overlay check pattern 202 of the first mask 200 and the second overlay check pattern 212 of the second mask 210 are not limited as the above first preferred embodiment of the present invention. In a second preferred embodiment of the present invention, a vertical view of a first overlay check pattern 302 of a first mask 300 and a second overlay check pattern 312 of a second mask 310 could be shown in FIG. 3A and FIG. 3B. Referring to FIG. 3A and FIG. 3B, two first vertical-trench pattern and a first horizontal-trench pattern are provided on the first overlay check pattern 302, and a second vertical-trench pattern and two second horizontal-trench pattern are provided on the second overlay check pattern 312. The second vertical-trench pattern is aligned with the midline position between the two first vertical-trench patterns, and between the two second horizontal-trench patterns, the corresponding first horizontal-trench pattern is aligned as the midline. In this second preferred embodiment of the present invention, the pattern design of the first overlay check pattern 302 and the second overlay check pattern 312 is different with the pattern design of the first overlay check pattern 202 and the second overlay check pattern 212 of the first preferred embodiment as the above description, but the detecting method and result could be the same as the first embodiment. Hence, other pattern design such as arranging two first vertical-trench patterns and two horizontal-trench patterns on the first overlay check pattern, and arranging a second vertical-trench pattern and a second vertical-trench pattern on the second overlay check pattern are also could be implemented according to the present invention.

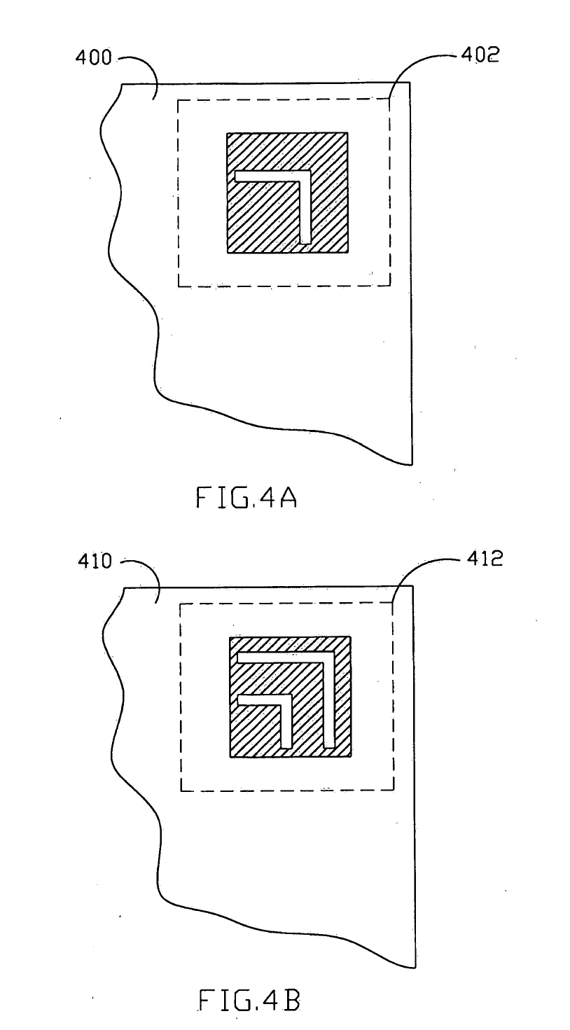

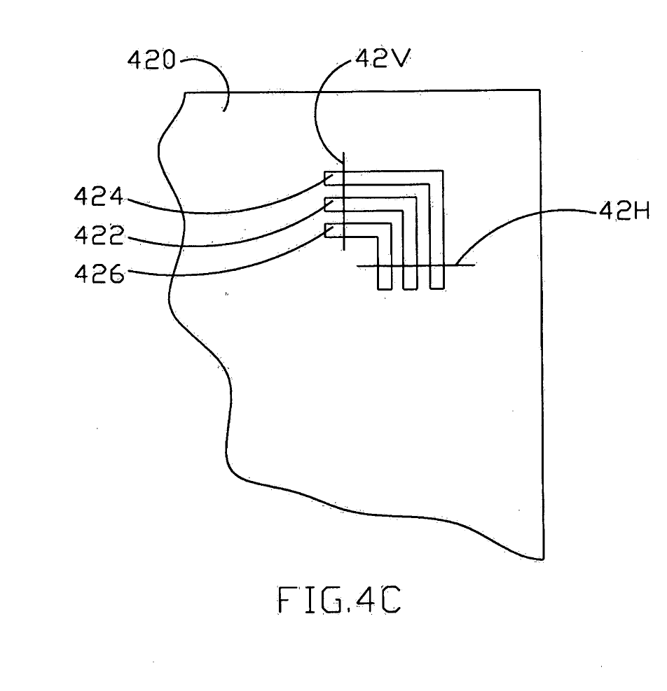

In a third preferred embodiment of the present invention, the arrangement of the first overlay check pattern 402 of a first mask 400 and the second overlay check pattern 412 of a second mask 410 could be shown in FIG. 4A and FIG. 4B. It is observed that the first vertical-trench pattern and the first horizontal-trench pattern are connected to form an L-shape pattern of the first overlay check pattern 402. And the second vertical-trench patterns and the second horizontal-trench patterns are also connected to form two L-shape patterns of the second overlay check pattern 412. Hence, in a photoresist layer 420, the first trench 422 transferred from the first mask 400 and the second trenches 424, 426 transferred from the second mask 410 could be passed through by a horizontal scan line 44H and a vertical scan line 44V, and the horizontal scan line 44H and the vertical scan line 44V are respectively perpendicular to the first trench 422. Next, a scanning electron microscope (not shown) is used to detect a vertical overlay error and a horizontal error between the first trench 422 and the second trenches 424, 426 along the horizontal scan line 44H and the vertical scan line 44V. Finally, the overlay error between the first mask 400 and the second mask 410 could be obtained according to this preferred embodiment.

As above descriptions of the first, second and third preferred embodiments according to the present invention, the present invention is utilizing a scanning electron microscope to detect the relative positions between the first trench and the second trench transferred from different masks during a multi-exposure process. In addition, with the high detecting resolution of the scanning electron microscope, the size of the trenches formed on the photoresist layer could be reduced and will not be limited to being formed on the scribe lines of a chip of the conventional method.

Skilled workers will further recognize that many changes may be made in the details of the above-described embodiment of this invention without departing from the underlying principles thereof. Accordingly, it will be appreciated that this invention is also applicable to color synchronization applications other than those found in multimedia projectors. The scope of the present invention should, therefore, be determined only by the following claims.

What is claimed is:

1. A overlay check pattern used in a multi-exposure process, comprising:
a first overlay check pattern, said first overlay check pattern is formed on a first mask and comprises a first vertical-trench pattern and a first horizontal-trench pattern; and
a second overlay check pattern, said second overlay check pattern is formed on a second mask and comprises a second vertical-trench pattern and a second horizontal-trench pattern, the forming position of said second vertical-trench pattern is parallel but not overlap with the forming position of said first vertical-trench pattern, and the forming position of said second horizontal-trench pattern is parallel but not overlap with the forming position of said first horizontal-trench pattern.

2. The overlay check pattern according to claim 1, wherein said first overlay check pattern is provided with a first vertical-trench pattern and a first horizontal-trench pattern, said second overlay check pattern is provided with two second vertical-trench patterns and two second horizontal-trench patterns, and between said two second vertical-trench patterns, said corresponding first vertical-trench pattern is aligned as the midline, and between said two second horizontal-trench patterns, said corresponding first horizontal-trench pattern is aligned as the midline.

3. The overlay check pattern according to claim 2, wherein said first vertical-trench pattern and said first horizontal-trench pattern are connected on said first mask, and said two vertical-trench patterns are connected with said corresponding two horizontal-vertical trench patterns one by one on said second mask.

4. The overlay check pattern according to claim 1, wherein said first overlay check pattern is provided with two first vertical-trench patterns and a first horizontal-trench pattern, said second overlay check pattern is provided with a second vertical-trench pattern and two second horizontal-trench patterns, and said second vertical-trench pattern is aligned with the midline position between said two first vertical-trench patterns, and between said two second horizontal-trench patterns, said corresponding first horizontal-trench pattern is aligned as the midline.

5. The overlay check pattern according to claim 1, wherein said first overlay check pattern is provided with two first vertical-trench patterns and two first horizontal-trench patterns, said second overlay check pattern is provided with a second vertical-trench pattern and a second horizontal-trench pattern, and said second vertical-trench pattern is aligned with the midline position between said two first vertical-trench patterns, and said second horizontal-trench pattern is aligned with the midline position between said two first horizontal-trench patterns.
